(19) United States
(12) Patent Application Publication
(10) Pub. No.: US 2016/0246088 A1
(43) Pub. Date: Aug. 25, 2016

(54) ARRAY SUBSTRATE, DISPLAY DEVICE AND FABRICATING METHOD OF ARRAY SUBSTRATE

(71) Applicants: HEFEI BOE OPTOELECTRONICS TECHNOLOGY CO., LTD., Hefei, Anhui (CN); BOE TECHNOLOGY GROUP CO., LTD., Beijing (CN)

(72) Inventors: Ming HU, Beijing (CN); Byung Cheon LIM, Beijing (CN); Xinxia ZHANG, Beijing (CN)

(21) Appl. No.: 14/389,267

(22) PCT Filed: Nov. 13, 2013
(86) PCT No.: PCT/CN2013/087026

§ 371 Date: Sep. 29, 2014

(30) Foreign Application Priority Data
May 30, 2013 (CN) 201310211609.9

(51) Int. Cl. G02F 1/1368; H01L 29/423; H01L 27/12; G02F 1/1343; G02F 1/1362

(52) U.S. Cl. CPC G02F 1/1368; G02F 1/13439; G02F 1/134309; G02F 1/136286; H01L 27/124; H01L 27/1259; H01L 29/42356; G02F 2001/136295

(57) ABSTRACT

An array substrate, a display device and a fabricating method of array substrate. The array substrate comprises: a substrate; a gate line and a gate electrode formed on the substrate; a first insulating layer covering the gate line and the gate electrode; a pixel electrode, a data line, a source electrode and drain electrode formed on the first insulating layer; a second insulating layer covering the pixel electrode, the data lines, the source electrode and the drain electrode; and a common electrode formed on second insulating layer. The second insulating layer comprises a first portion not covered by common electrode and a second portion covered by common electrode; the first portion has a first height from a top of the first portion to the substrate, the second portion has a second height from a top of the second portion to the substrate, the first height less than the second height.

### TECHNICAL FIELD

Embodiments of the present invention relate to an array substrate, a display device and a fabricating method of array substrate.

### BACKGROUND

Advanced super dimension switch (ADS) technology is wide-viewing-angle technology in liquid crystal display (LCD) field developed for large-size and high-resolution desktop monitors and LCD TV applications.

High aperture ratio ADS (HADS) technology further improves aperture ratio of a panel by changing positions of a common electrode and a pixel electrode in an ADS array substrate so as cover data signal lines and gate scanning signal lines by the common electrode.

However, a conventional HADS array substrate at least has the problem of low transmittance described as follows.

In an HADS array substrate, a common electrode substantially covers the entire panel, so that a coupling capacitance of the panel is relatively large, and hence the power consumption of the entire panel is relatively large. In order to reduce the power consumption of the panel, the coupling capacitance is typically reduced by increasing the thickness of an insulating layer covered by the common electrode.

But the transmittance can be reduced due to the thickened insulating layer upon reducing the coupling capacitance.

### SUMMARY

One embodiment of the present invention provides an array substrate comprising: a substrate; a gate line and a gate electrode formed on the substrate; a first insulating layer covering the gate line and the gate electrode; a pixel electrode, a data line, a source electrode and a drain electrode formed on the first insulating layer; a second insulating layer covering the pixel electrode, the data lines, the source electrode and the drain electrode; and a common electrode formed on the second insulating layer. The second insulating layer comprises a first portion covered by the common electrode and a second portion not covered by the common electrode; and the first portion has a first height from a top of the first portion to the substrate, the second portion has a second height from a top of the second portion to the substrate, and the first height is greater than the second height.

Another embodiment of the present invention provides a display device comprising the foregoing array substrate.

Another embodiment of the present invention provides a fabricating method of an array substrate, comprising: depositing a conductive film layer on a second insulating layer covering a pixel electrode, a data line, a source electrode and a drain electrode; and forming a common electrode by a patterning process using the conductive film layer, so that the second insulating layer comprises a first portion covered by the common electrode and a second portion not covered by the common electrode. The first portion has a first height from a top of the first portion to the substrate, the second portion has a second height from a top of the second portion to the substrate, and the first height is greater than the second height.

### BRIEF DESCRIPTION OF THE DRAWINGS

For better understanding technical solutions according to embodiments of the present invention, drawings of the embodiments will be described briefly below. Obviously, drawings in the following description only relate to some embodiments of the present invention, not for limiting the present invention.

FIG. 1 is a schematic view of an insulating layer of an array substrate according to an embodiment of the present invention;

FIGS. 2 and 3 are schematic views of two structures of a multilayer insulating layer of the array substrate according to an embodiment of the present invention;

FIG. 4 is a flowchart of a fabricating method of array substrate according to an embodiment of the present invention;

FIGS. 5 to 9 are schematic structural views of steps in the fabricating method of array substrate according to an embodiment of the present invention; and

FIG. 10 is a schematic view illustrating simulation results of the embodiment of the present invention.

### DETAILED DESCRIPTION

In order to make the purpose, technology solution and advantages of embodiments of the present invention more clear, technology solutions according to embodiments of the present invention will be described clearly and completely below with respect to drawings of embodiments of the present invention. It is understood that the described embodiments are part of but not all of embodiments of the present invention. Based on the described embodiments of the present invention, all other embodiments obtained by those of ordinary skilled in the art without any creative labor fall into the protective scope of the present invention.

Embodiments of the present invention provide an array substrate and a fabricating method thereof, so as to improve the transmittance of a display device. Moreover, the embodiment of the present invention further provides a display device comprising the array substrate.

The array substrate according to an embodiment of the present invention may comprise: a substrate; a gate line and a gate electrode formed on the substrate; a first insulating layer covering the gate line and the gate electrode; a pixel electrode, a data line, a source electrode and a drain electrode formed on the first insulating layer; a second insulating layer covering the pixel electrode, the data lines, the source electrode and the drain electrode; and a common electrode formed on the second insulating layer. The second insulating layer comprises a first portion covered by the common electrode and a second portion not covered by the common electrode; and the first portion has a first height from a top of the first portion to the substrate, the second portion has a second height from a top of the second portion to the substrate, the first height is greater than the second height.

In the embodiment of the present invention, the portion of the second insulating layer not covered by the common electrode is partially etched off in the fabricating process. Therefore, with the requirements of reducing the power consumption of a panel, the thickness of a part of the insulating layer is reduced, so that the traveling distance of partial light beams in the insulating layer can be reduced, and hence the transmittance of the entire panel can be improved.

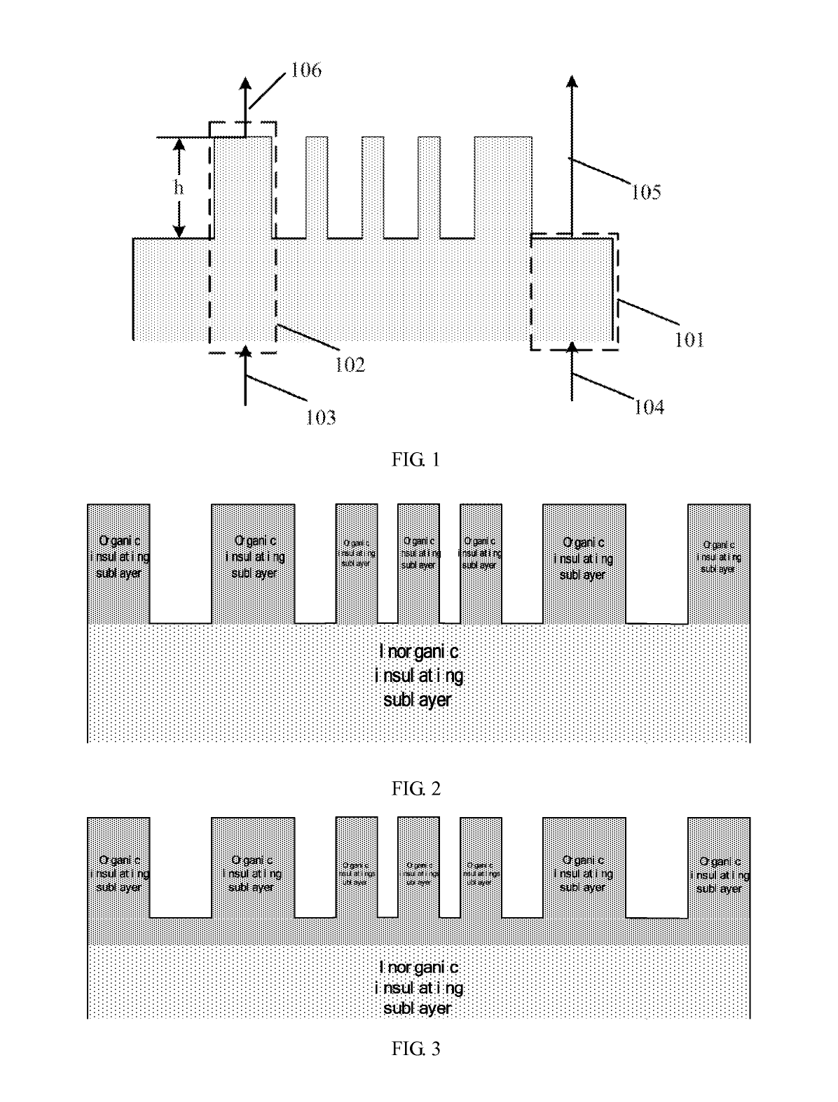

The array substrate according to an embodiment of the present invention will be described in more detail with reference to FIG. 1 to FIG. 3. FIG. 1 is a schematic view of an insulating layer of the array substrate according to an embodiment of the present invention, and FIGS. 2 and 3 are schematic views of two structures of a multilayer insulating layer of the array substrate according to an embodiment of the present invention.

As shown in FIG. 1, in the embodiment of the present invention, the second insulating layer comprises two portions, in which one portion 102 has a relative large height from a top of the portion 102 to the substrate; and the other portion 101 has a relative small height from a top of the portion 101 to the substrate. In comparison, a conventional insulating layer has a relatively uniform height from the top to the substrate.

At this point, it is assumed that a first incident light 104 with a first intensity passes through a first portion 101 to form a first exiting light 105, and a second incident light 103 with a first intensity passes through a second portion 102 to form a second exiting light 106.

Since the thickness of the first portion 101 of the insulating layer to be transmitted by the first incident light 104 is smaller than the thickness of the second portion 102 of the insulating layer transmitted by the second incident light 103, the intensity of the first exiting light 105 is higher than the intensity of the second exiting light 106.

With the array substrate according to an embodiment of the present invention, the traveling distance of the part of light beams in backlights in the insulating layer can be reduced by h, therefore the light intensity decrease caused by the entire insulating layer can be reduced, and hence the transmittance of the panel can be improved.

In a conventional HADS array substrate, in order to facilitate to form a common electrode on an insulating layer, the insulating layer is relatively flat. In comparison, in the array substrate according to an embodiment of the present invention, in order to reduce the light intensity decrease of backlights caused by the insulating layer, a part of the insulating layer is etched off, and meanwhile the common electrode is maintained at a certain height. Therefore, the etched portion needs satisfy two following conditions.

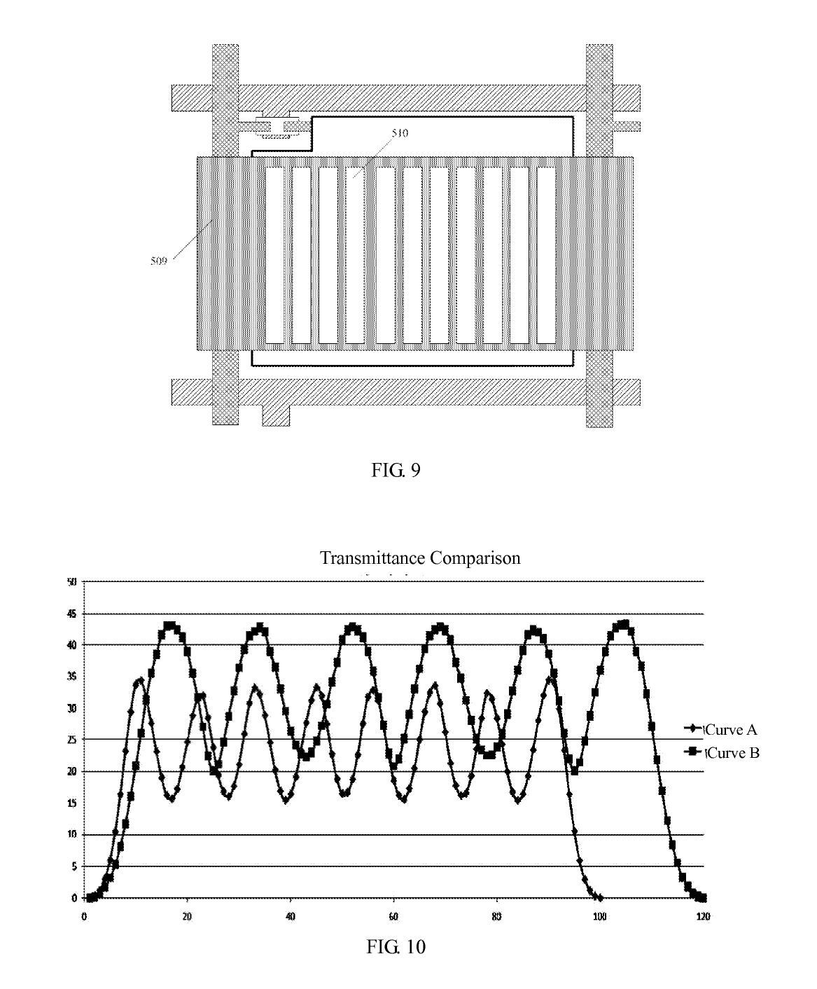

1. At least one portion of the etched portion opposes the pixel electrode in a direction perpendicular to the substrate, that is to say, at least a portion of the etched portion is overlapped with the pixel electrode in a direction perpendicular to the substrate. Preferably, the etched portion is completely overlapped with the pixel electrode, as shown in FIG. 9.

2. The etched portion is not covered by the common electrode.

Therefore, in the embodiment of the present invention, at least one portion of the second portion 102 opposes the pixel electrode in the direction perpendicular to the substrate.

In the embodiment of the present invention, as shown in FIG. 1, the height difference h between a first height of the first portion 101 and a second height of the second portion 102 is between 0.5 micron and 1.5 micron. But the embodiment of the present invention is not limited thereto.

In the embodiment of the present invention, the second insulating layer may be an insulating layer of various configurations. For instance, the second insulating layer may be a single layer insulating layer (e.g., an inorganic insulating layer) or may be a multilayer insulating layer.

When the second insulating layer is a multilayer insulating layer, the second insulating layer may comprise an inorganic insulating sublayer and an organic insulating sublayer formed on the inorganic insulating sublayer.

When the second insulating layer is a multilayer insulating layer, at least one portion of the second portion opposes the pixel electrode in the direction perpendicular to the substrate.

In some embodiments of the present invention, as shown in FIG. 2, the organic insulating sublayer corresponding to the portion not covered by the common electrode may be completely etched off, and only the inorganic insulating sublayer remains.

In some embodiments of the present invention, as shown in FIG. 3, the organic insulating sublayer corresponding to the portion not covered by the common electrode may only be partially etched off.

It is understood that the embodiments of the present invention are not limited thereto. For instance, some portions of the insulating layer may have a etching depth different from the etching depth of the other portions of the insulating layer.

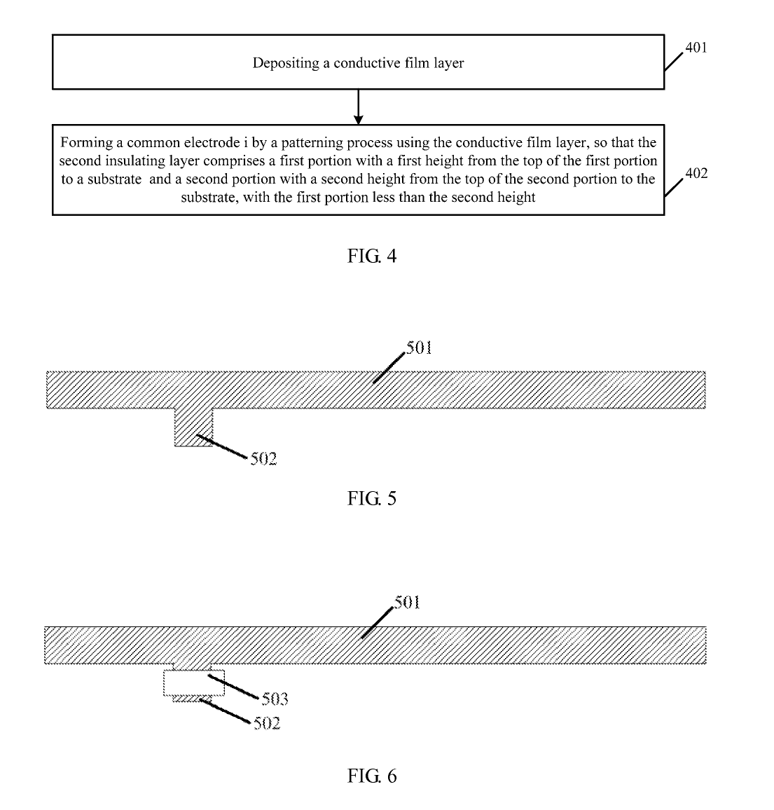

A fabricating method of array substrate according to an embodiment of the present invention will be described in more detail with reference to FIG. 4. FIG. 4 is a flowchart of the fabricating method of array substrate, according to an embodiment of the present invention. As shown in FIG. 4, the fabricating method according to an embodiment of the present invention may comprise following steps.

step 401: a conductive film layer is deposited on a second insulating layer covering a pixel electrode, a data line, a source electrode and a drain electrode.

step 402: a common electrode is formed by a patterning process using the conductive film layer, so that the second insulating layer comprises a first portion covered by the common electrode and a second portion not covered by the common electrode, and the first portion has a first height from the top of the first portion to a substrate and the second portion has a second height from the top of the second portion to the substrate, the first portion is greater than the second height.

In the embodiment of the present invention, before the step of depositing the conductive metal film layer, the fabricating method may further comprise following steps.

step 1, a gate metal film layer is deposited on the substrate and a gate line and a gate electrode are formed on the substrate by a patterning process;

step 2, a first insulating layer (namely a gate insulating layer), a semiconductor layer and a doped semiconductor layer are formed sequentially on the substrate provided with the gate line and the gate electrode, and an active layer silicon island is formed on the gate electrode by a patterning process;

step 3, a source/drain metal film is deposited and the pixel electrode, the data line, the source electrode and the drain electrode are formed on the first insulating layer by a patterning process; and

step 4, a second insulating layer is deposited to cover the pixel electrode, the data line, the source electrode and the drain electrode.

In some embodiments of the present invention, the second insulating layer may be a multilayer insulating layer. In this case, the step of depositing the second insulating layer may comprise following steps: depositing an inorganic insulating sublayer covering the pixel electrode, the data lines, the source electrode and the drain electrode; and depositing an organic insulating sublayer on the inorganic insulating sublayer.

In case that the second insulating layer is a multilayer insulating layer, in the step of forming the common electrode by the patterning process using the conductive film layer, so that the second insulating layer comprises the first portion covered by the common electrode and the second portion not covered by the common electrode, the common electrode is formed by transflective film technology and a portion of the organic insulating sublayer not covered by the common electrode is etched off.

In this case, since the common electrode layer and the organic insulating sublayer may be patterned with a single mask, no process is added in comparison with the conventional method. Meanwhile, since the common electrode layer and the organic insulating sublayer may be formed by a single exposure process, high-accuracy alignment of the common electrode and the organic film layer can be also achieved.

The fabricating method of array substrate according to an embodiment of the present invention will be described in more detail with reference to FIGS. 5 to 9. FIGS. 5 to 9 are schematic structural views showing the steps of the fabricating method of array substrate according to an embodiment of the present invention.

As shown in FIGS. 5 to 9, the fabricating method of array substrate according to an embodiment of the present invention may comprise following steps.

step A1, a gate metal film layer is deposited on a substrate;

step A2: a gate line 501 and a gate electrode 502 are formed on the substrate by a patterning process (only one gate line 501 and one gate electrode 502 are shown in FIG. 5);

step A3: as shown in FIG. 6, a first insulating layer (namely a gate insulating layer), a semiconductor layer and a doped semiconductor layer are deposited on the substrate provided with the gate lines 501 and the gate electrode 502 in sequence, and an active layer silicon island 503 is formed on the gate electrode 502 by a patterning process (one active layer silicon island 503 is shown in FIG. 6);

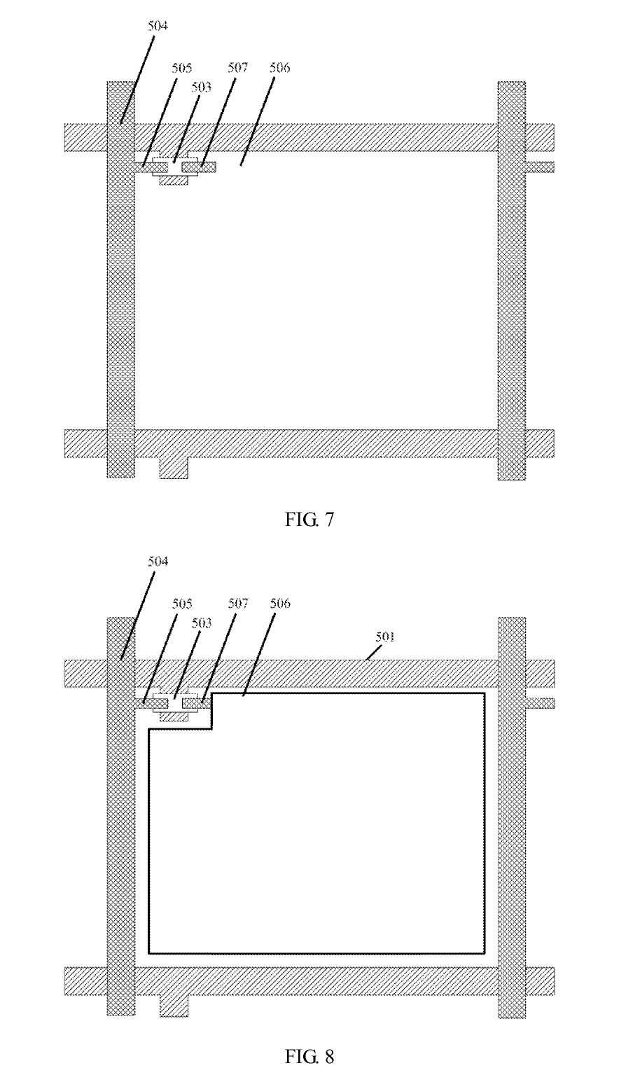

step A4: as shown in FIG. 7, a source/drain metal film is deposited and a data line 504, a source electrode 505 and a drain electrode 507 are formed on the first insulating layer by a patterning process, in which the data line 504 is connected to one end of the active layer silicon island 503 via the source electrode 505, and the drain electrode 507 is also connected to the other end of the active layer silicon island 503;

step A5: as shown in FIG. 8, a pixel electrode 506 is formed. The pixel electrode 506 is connected to the active layer silicon island 503 via the drain electrode 507;

step A6: a second insulating layer is deposited to cover the pixel electrode, the data line, the source electrode and the drain electrode;

step A7: a conductive film layer is deposited on the second insulating layer;

step A8: a portion of the second insulating layer not covered by a common electrode 509 is etched off by a patterning process at the same time of forming the common electrode 509 is, so that the portion of the second insulating layer not covered by the common electrode 509 is lower than a portion of the second insulating layer covered by the common electrode 509, as shown in FIG. 9 (it is noted that: for the convenience of understanding the structure of the entire array substrate, only a part of the common electrode 509 is shown, and in reality, the common electrode 509 can substantially cover the entire panel).

As shown in FIG. 9, a portion 510 of the conductive film layer is etched off so as to form a strip-like common electrode 509, and a portion of the insulating layer corresponding to the etched portion 510 of the conductive film layer is also etched off, so that the height of the portion of the second insulating layer not covered by the common electrode 509, (namely the insulating layer corresponding to the etched portion 510 of the conductive film layer), is lower than the portion of the second insulating layer covered by the common electrode 509.

Herein, it is noted that FIGS. 5 to 9 are only schematic structural views and do not represent the exact shapes and the sizes of the respective components of the actual array substrate product being produced. For instance, in the actual array substrate, the common electrode may aligned in a certain angle and the gate lines and the data lines may be not straight lines as shown in the figure. Therefore, the embodiments of the present invention are not limited to embodiments shown in FIGS. 5 to 9.

In the embodiment of the present invention, in comparison with a reference example of a conventional product with a thickness of the entire insulating layer of 1.5 micron, in the array substrate according to an embodiment of the present invention, the insulating layer is divided into two portions; one portion with a thickness of 1.5 micron corresponds to an overlapped portion of the common electrode and the pixel electrode; and the other portion with a thickness of 0.5 micron.

The results of the simulation experiment of the above cases are as shown in FIG. 10. FIG. 10 is a schematic view illustrating the simulation results of the electric field and the transmittance, in which the x axis represents the electric field and the y axis represents the transmittance. As shown in FIG. 10, a curve A is a simulation curve of the conventional product and a curve B is a simulation curve of the embodiment of the present invention.

It can be found from FIG. 10 that with the change of the applied electric field, the transmittance of the conventional array substrate is approximately between 15 and 34 percent, but the transmittance of the array substrate according to an embodiment of the present invention is approximately between 20 and 44 percent.

Therefore, it can be found from the simulation experiment that: compared with the conventional product, the transmittance of the panel according to the embodiment of the present invention can be improved.

It should be noted that the above embodiments are only for the purpose of describing technical proposal of the present invention rather than limiting it. While the present invention has been described in detail with reference to the above-mentioned embodiments, those of ordinary skill in the art should understand that they can modify the technical solution recorded in the above embodiments or conduct equivalent substitution for a part of technical features thereof and these modifications or substitutions will not make the nature of respective technical solution to depart from the spirit and scope of technical solutions of embodiments of the present invention.

1. An array substrate, comprising:
a substrate;
a gate line and a gate electrode formed on the substrate;
a first insulating layer covering the gate line and the gate electrode;
a pixel electrode, a data line, a source electrode and a drain electrode formed on the first insulating layer;
a second insulating layer covering the pixel electrode, the data lines, the source electrode and the drain electrode; and
a common electrode formed on the second insulating layer,
wherein the second insulating layer comprises a first portion not covered by the common electrode and a second portion covered by the common electrode; and the first portion has a first height from a top of the first portion to the substrate, the second portion has a second height from a top of the second portion to the substrate, the first height is less than the second height.

2. The array substrate according to claim 1, wherein the first portion of the second insulating layer not covered by the common electrode is overlapped with the pixel electrode viewing in a direction perpendicular to the substrate.

3. The array substrate according to claim 1, wherein the first height and the second height have a height difference between 0.5 micron and 1.5 micron.

4. The array substrate according to claim 1, wherein the second insulating layer is an inorganic insulating layer.

5. The array substrate according to claim 1, wherein the second insulating layer comprises an inorganic insulating sublayer and an organic insulating sublayer formed on the inorganic insulating sublayer; the common electrode is formed on the organic insulating sublayer; and the first portion is a portion of the inorganic insulating sublayer not covered by the common electrode.

6. A display device, comprising an array substrate,
the array substrate comprising:
a substrate;
a gate line and a gate electrode formed on the substrate;
a first insulating layer covering the gate line and the gate electrode;
a pixel electrode, a data line, a source electrode and a drain electrode formed on the first insulating layer;
a second insulating layer covering the pixel electrode, the data lines, the source electrode and the drain electrode; and
a common electrode formed on the second insulating layer,
wherein the second insulating layer comprises a first portion not covered by the common electrode and a second portion covered by the common electrode; and the first portion has a first height from a top of the first portion to the substrate, the second portion has a second height from a top of the second portion to the substrate, the first height is less than the second height.

7. A fabricating method of an array substrate, comprising:
depositing a conductive film layer on a second insulating layer covering a pixel electrode, a data line, a source electrode and a drain electrode; and
forming a common electrode by a patterning process using the conductive film layer, so that the second insulating layer comprises a first portion not covered by the common electrode and a second portion covered by the common electrode, and the first portion has a first height from a top of the first portion to the substrate, the second portion has a second height from a top of the second portion to the substrate, the first height is less than the second height.

8. The fabricating method according to claim 7, before the step of depositing the conductive film layer, further comprising:
step 1, depositing a gate metal film layer on the substrate and forming a gate and a gate electrode by a patterning process;
step 2, depositing a first insulating layer, a semiconductor layer and a doped semiconductor layer on the substrate formed with the gate line and the gate electrode sequentially, and forming an active layer silicon island on the gate electrode by a patterning process;
step 3, depositing a source/drain metal film and forming the pixel electrode, the data line, the source electrode and the drain electrode on the first insulating layer by a patterning process; and
step 4, depositing the second insulating layer covering the pixel electrode, the data line, the source electrode and the drain electrode.

9. The fabricating method according to claim 8, wherein the step of depositing the second insulating layer comprises:
depositing an inorganic insulating sublayer covering the pixel electrode, the data line, the source electrode and the drain electrode; and
depositing an organic insulating sublayer on the inorganic insulating sublayer.

10. The fabricating method according to claim 7, wherein in the step of forming the common electrode by the patterning process using the conductive film layer so that the second insulating layer comprises the first portion not covered by the common electrode and the second portion covered by the common electrode, the common electrode is formed by a transflective film technology and a portion of the organic insulating sublayer not covered by the common electrode is etched off.

11. (canceled)

12. The array substrate according to claim 2, wherein the first height and the second height have a height difference between 0.5 micron and 1.5 micron.

13. The array substrate according to claim 2, wherein the second insulating layer is an inorganic insulating layer.

14. The array substrate according to claim 2, wherein the second insulating layer comprises an inorganic insulating sublayer and an organic insulating sublayer formed on the inorganic insulating sublayer; the common electrode is formed on the organic insulating sublayer; and the first portion is a portion of the inorganic insulating sublayer not covered by the common electrode.

15. The display device according to claim 6, wherein the first portion of the second insulating layer not covered by the common electrode is overlapped with the pixel electrode viewing in a direction perpendicular to the substrate.

16. The display device according to claim 6, wherein the first height and the second height have a height difference between 0.5 micron and 1.5 micron.

17. The display device according to claim 6, wherein the second insulating layer is an inorganic insulating layer.

18. The display device according to claim 6, wherein the second insulating layer comprises an inorganic insulating sublayer and an organic insulating sublayer formed on the inorganic insulating sublayer; the common electrode is formed on the organic insulating sublayer; and the first portion is a portion of the inorganic insulating sublayer not covered by the common electrode.
